(19) United States
(12) Patent Application Publication
(10) Pub. No.: US 2015/0255954 A1
(43) Pub. Date: Sep. 10, 2015

(54) Method And Device For Producing Laser Emission

(71) Applicant: The Board of Trustees of The University of Illinois, Urbana, IL (US)

(72) Inventors: Milton Feng, Champaign, IL (US); Nick Holonyak, JR., Urbana, IL (US); Rohan Bambery, Urbana, IL (US); Fei Tan, San Jose, CA (US); Mong-Kai Wu, Hillsboro, OR (US); Michael Liu, Urbana, IL (US)

(21) Appl. No.: 14/469,132

(22) Filed: Aug. 26, 2014

Related U.S. Application Data
(60) Provisional application No. 61/948,199, filed on Mar. 5, 2014.

(51) Int. Cl. H01S 5/187; H01S 5/062; H01S 5/183; H01S 5/343

(52) U.S. Cl. CPC H01S 5/187; H01S 5/34313; H01S 5/06203; H01S 5/18369

(57) ABSTRACT

A method for producing laser emission, including the following steps: providing a layered semiconductor structure that includes a substrate, a lower reflector and a semiconductor collector region disposed over the substrate, a semiconductor base region disposed over the collector region, and a semiconductor emitter region disposed over the base region; providing, in the base region, at least one region exhibiting quantum size effects; depositing collector, base, and emitter electrodes respectively coupled with the collector, base, and emitter regions; disposing an insulating upper reflector over at least a portion of the emitter region; and applying electrical signals with respect to the collector, base, and emitter electrodes to produce laser emission from the base region in a vertical resonant optical cavity defined between the lower reflector and the insulating upper reflector.

### PRIORITY CLAIM

This application claims priority from U.S. Provisional Patent Application No. 61/948,199, filed Mar. 5, 2014, and said U.S. Provisional Patent Application is incorporated herein by reference.

### GOVERNMENT RIGHTS

This invention was made with Government support under contract number W911 NF-12-1-0394 awarded by the Army Research Office. The Government has certain rights in the invention.

### FIELD OF THE INVENTION

This invention relates to the field of light-emitting semiconductors and, more particularly, to transistor laser devices, methods of making such devices, and methods for producing laser emission.

### BACKGROUND OF THE INVENTION

The discovery of radiative recombination in the base of heterojunction bipolar transistors (HBTs) with high current density has led to the realization of the quantum-well (QW) light-emitting transistors (LETs) and transistor lasers (TLs) (see M. Feng, N. Holonyak, Jr. and W. Hafez, Appl. Phys. Lett. 84, 151 (2004); G. Walter, N. Holonyak, Jr., M. Feng, and R. Chan, Appl. Phys. Lett. 85, 4768 (2004); and M. Feng, N. Holonyak, Jr., G. Walter, and R. Chan, Appl. Phys. Lett. 87, 131103 (2005)). The QW transistor lasers possess a picosecond radiative recombination lifetime in the base (see H. W. Then, M. Feng, N. Holonyak, Jr., and C. H. Wu, Appl. Phys. Lett. 91, 033505 (2007); and G. Walter, C. H. Wu, H. W. Then, M. Feng and N. Holonyak, Jr., Appl. Phys. Lett., 94, 231125 (2009)), and thus are capable of extending the direct modulation bandwidth above 100 GHz. Since 2005, three-port TLs have demonstrated many unique characteristics, such as resonance-free microwave response (see M. Feng, H. W. Then, N. Holonyak, Jr., G. Walter, and A. James, Appl. Phys. Lett. 95, 033509 (2009)), simultaneous electrical and optical signal output at 40 Gb/s modulation (see F. Tan, R. Bambery, M. Feng, and N. Holonyak, Jr., Appl. Phys. Lett. 99, 061105 (2011)), voltage-operation switching (see A. James, N. Holonyak, Jr., M. Feng, and G. Walter, IEEE Photonics Technol. Lett. 19, 680 (2007)), and ultra-low relative intensity noise (RIN) (see F. Tan, R. Bambery, M. Feng, and Holonyak, Jr., Appl. Phys. Lett. 101, 15118 (2012)). The minority carrier diffusion transport in the short base of an HBT allows low base storage charge while maintaining high carrier supply rate (current) to sustain the stimulated emission. Owing to the fast diffusion process, carriers that cannot recombine in the base quantum wells are swept out by the reverse-biased base-collector (BC) junction, the fundamental of fast recombination lifetime in transistor lasers and LETs.

Regarding LETs and TLs and, generically, so-called “tilted-charge” light emitters (a tilted charge device getting its name from the energy diagram characteristic in the device's base region, which has, approximately, a descending ramp shape from the emitter interface to the collector (or drain, for a two terminal device) interface), reference can be made, for example, to U.S. Pat. Nos. 7,091,082, 7,286,583, 7,354,780, 7,535,034, 7,693,195, 7,696,536, 7,711,015, 7,813,396, 7,888,199, 7,888,625, 7,953,133, 7,998,807, 8,005,124, 8,179,937, 8,179,939, 8,494,375, and 8,509,274; and U.S. Patent Application Publication Numbers US2005/0040432, US2005/0054172, US2008/0240173, US2009/0134939, US2010/0034228, US2010/0202483, US2010/0202484, US2010/0272140, US2010/0289427, US2011/0150487, and US2012/0068151; and to PCT International Patent Publication Numbers WO/2005/020287 and WO/2006/093883, as well as to the publications referenced in U.S. Patent Application Publication Number US2012/0068151.

A high “Q” vertical cavity configuration TL with distributed Bragg reflectors (DBR) can provide advantages over an edge-emitting TL in terms of smaller optical cavity volume, lower mirror loss, lower parasitics, and a lower threshold base current, and can be employed as a high speed directly modulated laser for energy efficient data transmission. The current-injected vertical cavity surface-emitting laser (VCSEL) using Au-coated mirrors was first reported in 1979 (see H. Soda, K. Iga, C. Kitahara, and Y. Suematsu, Jpn. J. Appl. Phys. 18, 2329 (1979)); however, the VCSEL exhibited a relatively high threshold due to lack of current and mode confinements. The VCSEL with native oxide confinement was first reported in 1994 and achieved relatively lower threshold (see D. L. Huffaker, D. G. Deppe, K. Kumar and T. J. Roger, Appl. Phys. Lett. 65, 2844 (1994).). Small volume and high-Q VCSELs now have gained popularity in low power-consuming short-haul interconnect systems. Further recent developments relating to vertical cavity transistor lasers (VCTLs) are disclosed in M. K. Wu, M. Feng, and Nick Holonyak, Jr., IEEE Photonics Technol. Lett. 24, 1346 (2012); M. K. Wu, M. Feng, and Nick Holonyak, Jr., Appl. Phys. Lett. 101, 081102 (2012); and the Patents and Published Patent Applications referenced above.

Optical interconnect technologies capable of Tb/s are being developed to meet the burgeoning demand for data transfer speeds by computing, communications, public health and national security applications. Oxide-confined vertical cavity surface emitting lasers (VCSELs), first referenced above, are of great interest because of their ability to deliver high bandwidth operation simultaneously with low power consumption; demonstrated by an energy consumption of <1 pJ/bit @ 40 Gb/s (see, for example, P. Westbergh, R. Safaisini, E. Haglund, J. S. Gustaysson, A. Larsson, M. Geen, R. Lawrence, and A. Joel, IEEE Photon. Technol. Lett., vol. 25, no. 8, pp. 768-771, Apr. 15, 2013; P. Wolf, P. Moser, G. Larisch, H. Li, J. A. Lott, and D. Bimberg, Electron. Lett., vol. 49, no. 10, pp. 666, May 2013; and F. Tan, M. K. Wu, M. Liu, M. Feng, and N. Holonyak, Jr, IEEE Photon. Technol. Lett., vol. 26, no. 3, pp 289-292, Feb. 1, 2014.). The intrinsic modulation speed of the VCSEL, however, is limited by the spontaneous recombination T_{b,spon} lifetime in its diode laser. The slow T_{b,spon} causes the device to exhibit a large carrier-photon relaxation oscillation peak (>3 dB) at the resonant frequency; adversely affecting signal integrity and the output waveform.

While device scaling, optimized cavity design and reduction of parasitic capacitance are techniques pursued to increase the bandwidth of high-speed VCSELs by mitigating a number of extrinsic factors, there are two methods being currently employed to increase the intrinsic performance of the VCSEL. Relief etching is used to lower the reflectivity of the top DBR and reduce photon lifetime Tₚ, and it has resulted in devices with 28 GHz bandwidth and 57 Gb/s error free transmission (see P. Westbergh, J. S. Gustaysson, B. Kogel, A. Haglund, A. Larsson, supra; P. Westbergh, E. P. Haglund, E. Haglund, R. Safaisini, J. S. Gustaysson, A. Larsson, Electron. Lett., vol. 49, no. 16, pp. 1021-1023, Aug. 1, 2013). Secondly, the Purcell effect has been leveraged in micro-cavity VCSELs to reduce the recombination lifetime T_{b,spon} resulting in a modulation bandwidth of 22 GHz and 40 Gb/s error-free transmission (see F. Tan, M. K. Wu, M. Liu, M. Feng, and N. Holonyak, Jr, supra; C. H. Wu, F. Tan, M. K. Wu, M. Feng, and N. Holonyak, Jr., J. Appl. Phys., vol. 109, no. 5, pp. 053112-1-053112-9, March 2011; and H. Wu, H. W. Then, M. Feng, N. Holonyak, Jr., Appl. Phys. Lett. Vol. 96, no. 13, pp. 131108-1-131108-3 March 2010.). The Purcell enhancement factor is around ˜2 to 3 indicating that T_{b,spon} is approximately reduced to ˜0.5 ns in a VCSEL. Despite promising results from reducing the recombination and photon lifetimes in VCSELs, it is expected that the modulation bandwidth will be limited to ˜30 GHz.

The transistor laser has demonstrated a 30-fold reduction in recombination lifetime T_{b,spon} in the base quantum wells to ˜30 ps (see Walter, M. Feng, N. Holonyak, Jr., R. Chan, Appl. Phys. Lett. Vol. 85, no. 20, pp. 4768-4770, Nov. 2004; M. Feng, N. Holonyak Jr., A. James, K. Comino, G. Walter, and R. Chan, Appl. Phys. Lett. vol.89, no. 11, pp. 113504-1-113504-3, September 2006; and G. Walter, C. H. Wu, H. W. Then, M. Feng, and N. Holonyak Jr., Appl. Phys. Lett. vol. 94, no. 24, pp. 241101-1-241101-3, June 2009). It has leveraged this reduction to demonstrate high speed 20 Gb/s voltage and current modulation (see R. Bambery, F. Tan, M. Feng, and N. Holonyak, Jr., IEEE Photon. Technol. Lett. vol. 25, no. 9, pp. 859-862, May 1, 2013), a reduced resonance amplitude and drastically lower relative intensity noise than diode lasers (see M. Feng, H. W. Then, N. Holonyak, Jr., G. Walter, and A. James, Appl. Phys. Lett. vol. 95, no. 3, pp. 033509-1-033509-3, Jul. 2009; and F. Tan, R. Bambery, M. Feng, and Holonyak, Jr., Appl. Phys. Lett. vol. 101, no. 15, pp. 151118-1-151118-3, Oct. 2012). A relatively low power vertical cavity transistor laser (VCTL) has been demonstrated, and with the aforementioned characteristics, and the ability for further scaling, the transistor laser is expected to be a compelling technology for low power data transmission over 100 Gb/s (see M. K. Wu, M. Feng, and Nick Holonyak, Jr., IEEE Photonics Technol. Lett. vol. 24, no. 15, pp. 1346-1348. Aug. 1, 2012; M. K. Wu, M. Feng, and N. Holonyak, Jr., Appl. Phys. Lett. vol. 101, no. 8, pp. 081102-1-081102-3, August 2012; M. K. Wu, M. Liu, F. Tan, M. Feng, and Nick Holonyak, Jr., Appl. Phys. Lett., vol. 103, no. 1, 011104 July 201; and M. Feng, N. Holonyak Jr., H. W. Then, and G. Walter, Appl. Phys. Lett. vol. 91, no. 5, pp. 053501-1-053501-3 July 2007).

Nonetheless, as will be explained hereinafter, there are still factors present which result in less than ideal characteristics of offset voltage and collector threshold voltage for stimulated emission in certain device configurations, and it is among the objectives hereof to improve these and other performance characteristics of transistor laser devices and also improve techniques for making such improved devices.

### SUMMARY OF THE INVENTION

In an embodiment hereof, improved collector offset voltage and power dissipation in a vertical cavity transister laser (VCTL) are achieved by, inter alia, disposing the emitter contact on the top of several pairs (e.g. four pairs) of a GaAs/AlGaAs distributed Bragg reflector (DBR) to reduce emitter resistance and subsequently depositing several pairs (e.g. eleven pairs) of SiO₂/TiO₂ to improve cavity photon confinement for low threshold current. This approach permits considerable reduction of the emitter series resistance that is manifest in the transistor I_{C}-V_{CE} characteristics as the collector offset voltage. In addition, the reduction in epitaxially grown GaAs/AlGaAs DBR from a previously used 25 pairs, to 4 pairs, also results in an improved process control in ICP etch and selectivity. The procedural steps of the invention and the resulting techniques and structures demonstrate a number of advantages of the invention.

In accordance with a form of the invention, a method is set forth for producing laser emission, including the following steps: providing a layered semiconductor structure that includes a substrate, a lower reflector and a semiconductor collector region disposed over said substrate, a semiconductor base region disposed over said collector region, and a semiconductor emitter region disposed over said base region; providing, in said base region, at least one region exhibiting quantum size effects; depositing collector, base, and emitter electrodes respectively coupled with said collector, base, and emitter regions; disposing an insulating upper reflector over at least a portion of said emitter region; and applying electrical signals with respect to said collector, base, and emitter electrodes to produce laser emission from said base region in a vertical resonant optical cavity defined between said lower reflector and said insulating upper reflector. In a preferred embodiment of this form of the invention, the step of disposing an insulating upper reflector over at least a portion of said emitter region comprises disposing an insulating distributed Bragg reflector over at least a portion of said emitter region. The insulating Bragg reflector can comprise alternating layers of different insulating materials, for example alternating layers of SiO₂ and TiO₂. An embodiment of this form of the invention further comprises disposing, over said at least a portion of said emitter region, a first reflector comprising a DBR of alternating semiconductor materials of different composition, and disposing said insulating upper reflector over at least said first reflector. In this embodiment, the insulating upper reflector is disposed over at least said first reflector, after depositing of said collector, base, and emitter electrodes.

In accordance with another form of the invention, a light-emitting semiconductor device is set forth, and comprises: a layered semiconductor structure that includes a substrate, a lower reflector and a semiconductor collector region disposed over said substrate, a semiconductor base region disposed over said collector region, and a semiconductor emitter region disposed over said base region; at least one region, in said base region, exhibiting quantum size effects; collector, base, and emitter electrodes respectively coupled with said collector, base, and emitter regions; an insulating upper reflector disposed over at least a portion of said emitter region, said insulating upper reflector comprising an insulating distributed Bragg reflector over at least a portion of said emitter region; whereby, application of electrical signals with respect to said collector, base, and emitter electrodes is operative to produce laser emission from said base region in a vertical resonant optical cavity defined between said lower reflector and said insulating upper reflector. In a preferred embodiment of this form of the invention, the insulating distributed Bragg reflector over at least a portion of said emitter region comprises an insulating Bragg reflector that includes alternating layers of different insulating materials, for example, alternating layers of SiO₂ and TiO₂. In this embodiment a first reflector is disposed over said at least a portion of said emitter region, said first reflector comprising a DBR of alternating semiconductor materials of different composition, and said insulating upper reflector is deposited over at least said first reflector and over said base and emitter electrodes.

In accordance with still another form of the invention, a method is set forth for making a light-emitting semiconductor structure, including the following steps: providing a layered semiconductor structure that includes a substrate, a lower reflector and a semiconductor collector region disposed over said substrate, a semiconductor base region disposed over said collector region, and a semiconductor emitter region disposed over said base region; providing, in said base region, at least one region exhibiting quantum size effects; depositing collector, base, and emitter electrodes respectively coupled with said collector, base, and emitter regions; disposing an insulating upper reflector over at least a portion of said emitter region, said disposing of an insulating upper reflector comprising disposing an insulating distributed Bragg reflector over at least a portion of said emitter region.

Further features and advantages of the invention will become more readily apparent from the following detailed description when taken in conjunction with the accompanying drawings.

### BRIEF DESCRIPTION OF THE DRAWINGS

FIG. 1 is a graph showing in (a) a relatively large offset voltage in the I_{C}-V_{CE} characteristics of a reference prior art oxide confined vertical cavity transistor laser device with 25 pairs of Al_{0.12}Ga_{0.88}As/Al_{0.9}Ga_{0.1}As as a top DBR, and showing in (b) a relatively large collector threshold voltage of 2.72 V in the L-V_{CE} optical characteristic of the device.

FIG. 2 is a schematic cross-sectional diagram of the reference prior art oxide confined vertical cavity transistor laser device with 25 pairs of Al_{0.12}Ga_{0.88}As/Al_{0.9}Ga_{0.1}As as a top DBR.

FIG. 3 is a schematic cross-sectional diagram of a vertical cavity transistor laser in accordance with an embodiment of the invention, in which, inter alia, emitter resistance is reduced by placing the emitter contact on the top of 4 pairs of the GaAs/AlGaAs DBR and employing a subsequently deposited dielectric DBR mirror, resulting in improved collector offset voltage.

FIG. 4 shows the emission spectra of a resonant cavity light-emitting transistor (RCLET), without DBR mirror, and a vertical cavity transistor laser (VCTL), with deposited DBR mirror and in accordance with an embodiment hereof, at −75° C. with I_{B}=2.5 mA and V_{CE}=2V. The inset is a log plot of the stimulated emission spectra of 4×3.3 μm² microcavity VCTL.

FIG. 5 is a graph showing, for an embodiment of the invention, in (a) a relatively smaller offset voltage in the I_{C}-V_{CE} characteristic, and in (b), a relatively small collector threshold voltage (of about 1.5 V) in the L-V_{CE} optical characteristic of the device. The characteristics are for a 4×3.3 μm² μ-cavity TL for I_{B}=0-3 mA. The device shows smaller offset voltage increments and a more pronounced photon-assisted tunneling effect at higher V_{CE} as compared to the VCTL of FIG. 1.

### DETAILED DESCRIPTION

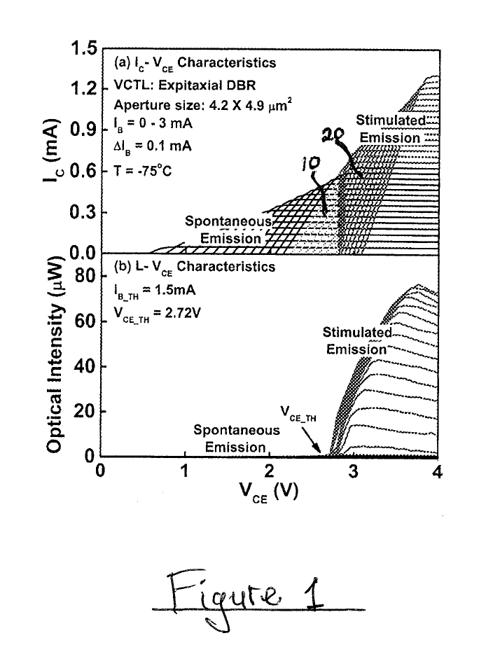

FIG. 1 illustrates, in (a), the relatively large offset of collector I_{C}-V_{CE} and, in (b), the corresponding optical output L-V_{CE} characteristics, of a previously reported oxide-confined vertical cavity transistor laser (“oxide-VCTL”) (see M. Liu, M. K. Wu, M. Feng, and N. Holonyak, Jr., J. Appl. Phys. vol. 114, no. 16, pp. 163104-163104-9, October 2013), with emitter metal placed on top of 25 pairs of Al_{0.12}Ga_{0.88}As/Al_{0.9}Ga_{0.1}As as the top DBR. FIG. 1 (a) shows a high offset voltage which increases with the base current indicating that the higher V_{CE} voltage is required to bias the device in the forward active mode. In the VCTL, the stimulated emission (laser output) is determined by i) the holes supplied via the base current I_{B}, ii) the electrons injected by the emitter into the base (I_{E}) via the voltage across the emitter/base junction (V_{BE}), and iii) the reverse bias on the base/collector junction (V_{CB}) that determines the boundary condition at the base/collector (BC) junction. Therefore, the additional voltage drop due to emitter series resistance shifts the stimulated emission operation toward the higher V_{CE}(=V_{CB}+V_{BE}) region. In the VCTL, the collector threshold voltage (V_{CE}_{_{—}}_{TH}) is defined as the bias voltage required for stimulated emission when base current is greater than the threshold current, which is denoted as I_{B}_{_{—}}_{TH}. The lines in region 10 of FIG. 1 represent the regime where the base current is greater than the threshold current, however the optical output of the device is incoherent spontaneous emission. With the transistor biased in saturation mode, holes in the base diffuse to the collector due to a forward bias on the BC junction. The terminal base current is then required to support both base recombination (radiative) and the hole leakage current to the collector. Thus, for a given terminal base current above the laser threshold current in FIG. 1 (a), the base recombination current may still be lower than laser threshold (region 10 in FIG. 1(a)). When the hole leakage is reduced due to a reverse bias on the BC junction, the base recombination current will then be above laser threshold current (region 20 in FIG. 1 (a)). As a result, a collector voltage threshold is required to define laser threshold in transistor in addition to base threshold current (I_{B}_{_{—}}_{TH}) to account for hole confinement in the base by the base-collector barrier. The VCTL shows a collector voltage threshold V_{CE}_{_{—}}_{TH}=2.72 V as shown in FIG. 1 (b), which results in higher power consumption to achieve laser operation. The cavity dimensions determined from the optical mode spacing in the emission spectra are 4.2×4.9 μm². Aperture size reduction will further increase the offset voltage due to the increase in the emitter series resistance.

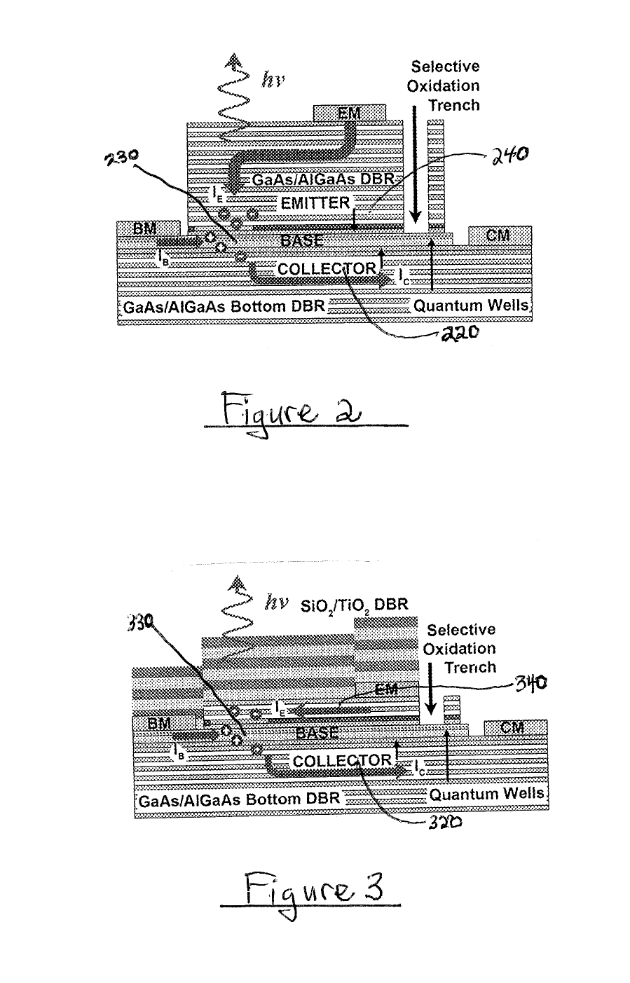

The device structure and fabrication are described next. The vertical cavity transistor laser structure is different, in respects to be described, from devices of the type reported previously, for example, in M. K. Wu, M. Feng, and Nick Holonyak, Jr., Appl. Phys. Lett. Vol. 101, no. 8, pp. 081102-1-081102-3, August 2012. FIG. 2 is a diagram illustrating the layer structure and operation of a vertical cavity transistor laser (VCTL) with top and bottom GaAs/AlGaAs DBRs as described, for example, in M. K. Wu, M., Liu, F. Tan, M. Feng, and N. Holonyak, Jr., Appl. Phys. Lett., Vol. 103, 011104 (2013). FIG. 3 is a diagram of a device in accordance with an embodiment of the invention and which can be made using a technique in accordance with an embodiment of the method of the invention.

An example of the prior device (e.g. in FIG. 2) includes 35 pairs of bottom DBRs followed by a light-emitting transistor structure that includes the indicated collector, base, and emitter regions, with quantum wells in the p+ base 230. The active region contains an n-type In_{0.49}Ga_{0.51}P emitter region 240, a heavily doped p-type Al_{0.05}Ga_{0.95}As base 230 with two undoped In_{0.2}Ga_{0.8}As QWs, a lightly doped n-type Al_{0.12}Ga_{0.88}As layer as a collector, and a heavily doped n-type GaAs sub-collector on the 35-pair bottom DBR. Above the emitter, a 98 nm Al_{0.08}Ga_{0.02}As layer is grown as a selective oxidation layer, followed by about twenty-five pairs of Al_{0.12}Ga_{0.88}As/Al_{0.9}Ga_{0.1}As of upper DBR.

In the present embodiment, as illustrated in FIG. 3, only four pairs of the Al_{0.12}Ga_{0.88}As/Al_{0.9}Ga_{0.1}As top DBR are grown instead of the typical structure with 25 pairs for the top DBR. In FIG. 3, the collector, base (with quantum wells), and emitter are represented at 320, 330, and 340, respectively. An example of fabrication comprises two low-pressure inductively coupled plasma (ICP) dry etch steps, two selective oxidation steps, one dilute citric acid wet etch, and three contact metallizations. After these are completed, the device is coated conformally with polyimide and vias are defined lithographically with an oxygen plasma etch. Ti/Au interconnect metal is deposited to complete the RCLET (resonant cavity light emitting transistor). For the final step of vertical cavity transistor laser fabrication, the polyimide on top of the emitter is removed by oxygen plasma and, in this embodiment, 11 pairs of SiO₂/TiO₂ are then deposited by e-beam evaporation into windows defined by a bi-layer photoresist lift-off process, leaving a highly reflective dielectric mirror on the top of the emitter cavity. The refractive indices of SiO₂ and TiO₂ at 975 nm wavelength are 1.42 and 1.85, and the designated thicknesses of SiO₂ and TiO₂ layers are 172 and 132 nm, respectively. The reflectivity of this SiO₂/TiO₂ dielectric mirror on a planar GaAs test substrate was measured as 98.3% at 975 nm.

The emitter metal is deposited on the top of the 4 pairs of the Al_{0.12}Ga_{0.88}As/Al0.9Ga_{0.1}As DBR. A cross section showed a shallow 1^{st} selective oxidation near the base metal and a deep 2^{nd} oxidation from the trench to the right. This eliminates unwanted recombination beneath the emitter metal. The base metal surrounds the cavity on three sides. As indicated, there are 11 pairs of SiO₂/TiO₂ dielectric DBR mirror deposited on the top of the cavity in this embodiment. It is observed that the base/collector thickness is very thin as compared to the emitter cap, and it may be possible to further reduce the 1^{st} oxidation depth to reduce the extrinsic base resistance. However, the cavity Q might suffer if the 1^{st} oxidation is too shallow due to the imperfect deposition morphologies around the sidewall.

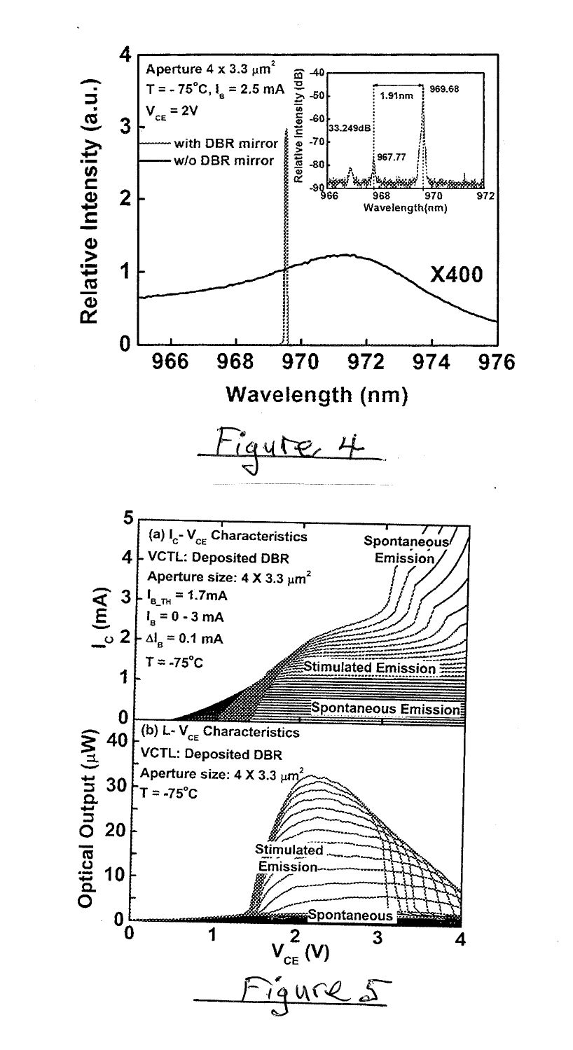

FIGS. 4 and 5 are useful in describing experimental results and analysis of the FIG. 3 embodiment. FIG. 4 shows the emission spectra of a resonant cavity light-emitting transistor (RCLET), without DBR mirror, and a vertical cavity transistor laser (VCTL), with deposited DBR mirror and in accordance with an embodiment hereof, at −75° C. with I_{B}=2.5 mA and V_{CE}=2V. The inset is a log plot of the stimulated emission spectra of 4×3.3 μm² microcavity VCTL. The measurement is taken at −75° C. since the QW emission is detuned from bottom DBR mirror at room temperature. The emission from the RCLET (without deposited mirror) has a broad peak at 971.3 nm with a full wave half maximum (FWHM) of 6 nm. After depositing the 11 pairs of the SiO₂/TiO₂ DBR the device shows stimulated emission at 969.68 nm with a FWHM smaller than 0.3 A. The inset of FIG. 4 shows the stimulated emission spectra on a logarithmic scale. It shows three distinct modes. The mode spacing between the fundamental mode and first excited mode is 1.91 nm with a side mode suppression ratio (SMSR) of 33.25 dB. Using this mode spacing, the aperture of the device is estimated to be 4×3.3 μm², making it the smallest reported transistor laser.

FIG. 5 shows (a) the collector I_{C}-V_{CE} and (b) the corresponding optical L-V_{CE} characteristics of the deposited mirror VCTL at −75° C. The deposited mirror VCTL has an electrical gain (β) of 0.6 to 1.2, which is larger than that of the previously reported VCTL (⊕˜0.4 to 0.5), even though the transistor structure is the same, i.e. the same base/collector and QW design. The difference is attributed to the lower reflectivity of the mismatched dielectric mirror, resulting in reduced enhancement of spontaneous recombination. The deposited mirror VCTL shows shifting from spontaneous emission to stimulated emission when base current I_{B}>1.7 mA and collector voltage V_{CE}>1.65 V. In the VCTL, the emitter resistance is much higher compared to the edge emitting TL, which causes the increased collector offset voltage. It becomes especially challenging in realizing small cavity VCTLs since the emitter resistance increases with a decrease in the aperture dimensions. From the base current dependent offset voltage, the emitter resistance can be roughly estimated by R_{E}˜ΔV_{offset}/ΔI_{B}, where R_{E}, ΔV_{offset}, and ΔI_{B} are emitter resistance, offset voltage difference, and corresponding base current span, respectively. In FIG. 1 (a), for the prior VCTL with a as-grown 25-pair DBR, the emitter resistance is estimated to be 837 Ω for a 4.2×4.9 μm² aperture with an offset voltage 3.08 V at I_{B}=3 mA. In the deposited dielectric DBR VCTL, the emitter resistance of a 4×3.3 μm² aperture is drastically reduced to only 303 Ω, and the offset voltage is reduced to 1.39 V at I_{B}=3 mA. It can be observed that the emitter aperture is 36% smaller while the emitter resistance is also 64% lower. The reduced emitter resistance allows for lower operating voltages. The optical offset voltage also reduces to 1.4 V. This reduces the required V_{CE} to operate in the forward active region.

The deposited dielectric DBR VCTL exhibits a higher threshold current density due to lower cavity Q than the epitaxially grown top DBR VCTL. The base current densities of the deposited DBR and original VCTLs are 12.9, and 7.2 kA/cm², respectively. However, the total power consumption of the deposited mirror VCTL is greatly reduced. The electrical power consumption of a VCTL can be calculated as P=I_{C}*V_{CE}+I_{B}*V_{BE}. With the prior VCTL (FIG. 1) biased at knee voltage and the threshold current I_{B}=1.5 mA, the corresponding measured V_{CE}, V_{BE}, and I_{C} are measured as 2.96 V, 4.26V and 0.74 mA, respectively. This gives a total power consumption of 8.98 mW. On the other hand, at threshold, the deposited mirror VCTL bias points are: V_{CE}, V_{BE}, and I_{C} of 1.65V, 2.65V and 1.1 mA, respectively. The total power reduces to 6.32 mW (a reduction of ˜29.6%).

As has been described, an improved collector offset voltage and reduced dissipated power have been demonstrated in the VCTL of the invention and made in accordance with the techniques hereof. As compared to a prior art VCTL, the deposited-mirror VCTL shows low V_{CE} bias operation in the forward active region and lower power consumption at threshold.

1. A method for producing laser emission, comprising the steps of:
providing a layered semiconductor structure that includes a substrate, a lower reflector and a semiconductor collector region disposed over said substrate, a semiconductor base region disposed over said collector region, and a semiconductor emitter region disposed over said base region;
providing, in said base region, at least one region exhibiting quantum size effects;
depositing collector, base, and emitter electrodes respectively coupled with said collector, base, and emitter regions;
disposing an insulating upper reflector over at least a portion of said emitter region; and
applying electrical signals with respect to said collector, base, and emitter electrodes to produce laser emission from said base region in a vertical resonant optical cavity defined between said lower reflector and said insulating upper reflector.

2. The method as defined by claim 1, wherein said step of disposing an insulating upper reflector over at least a portion of said emitter region comprises disposing an insulating distributed Bragg reflector over at least a portion of said emitter region.

3. The method as defined by claim 2, wherein said step of disposing an insulating distributed Bragg reflector over at least a portion of said emitter region comprises providing an insulating Bragg reflector comprising alternating layers of different insulating materials.

4. The method as defined by claim 2, wherein said step of disposing an insulating distributed Bragg reflector over at least a portion of said emitter region comprises providing an insulating Bragg reflector comprising alternating layers of SiO₂. and TiO₂.

5. The method as defined by claim 2 further comprising disposing, over said at least a portion of said emitter region, a first reflector comprising a DBR of alternating semiconductor materials of different composition, and disposing said insulating upper reflector over at least said first reflector.

6. The method as defined by claim 2, further comprising disposing, over said at least a portion of said emitter region, a first reflector comprising a DBR of alternating semiconductor materials of different composition, and disposing said insulating upper reflector over at least said first reflector, after depositing of said collector, base, and emitter electrodes.

7. The method as defined by claim 5, further comprising disposing, over said at least a portion of said emitter region, said first reflector, before depositing collector, base, and emitter electrodes respectively coupled with said collector, base, and emitter regions, and disposing over at least said first reflector, said insulating upper reflector after depositing of said collector, base, and emitter electrodes.

8. The method as defined by claim 7, wherein said step of disposing of said insulating upper reflector over at least said first reflector comprises disposing said insulating upper reflector over at least a portion of said emitter region and over said emitter electrode.

9. The method as defined by claim 7, wherein said step of disposing of said insulating upper reflector over at least said first reflector comprises disposing said insulating upper reflector over at least a portion of said emitter region and over said emitter electrode and said base electrode.

10. The method as defined by claim 9, wherein said step of providing an insulating upper reflector comprises providing an insulating Bragg reflector comprising several pairs of alternating layers of different insulating materials.

11. The method as defined by claim 10, wherein said several pairs of alternating layers of different insulating materials comprises of the order of ten pairs of said alternating layers of insulating materials.

12. A light-emitting semiconductor device, comprising:
a layered semiconductor structure that includes a substrate, a lower reflector and a semiconductor collector region disposed over said substrate, a semiconductor base region disposed over said collector region, and a semiconductor emitter region disposed over said base region;
at least one region, in said base region, exhibiting quantum size effects;
collector, base, and emitter electrodes respectively coupled with said collector, base, and emitter regions; and
an insulating upper reflector disposed over at least a portion of said emitter region, said insulating upper reflector comprising an insulating distributed Bragg reflector over at least a portion of said emitter region;
whereby, application of electrical signals with respect to said collector, base, and emitter electrodes is operative to produce laser emission from said base region in a vertical resonant optical cavity defined between said lower reflector and said insulating upper reflector.

13. The device as defined by claim 12, wherein said insulating distributed Bragg reflector over at least a portion of said emitter region comprises an insulating Bragg reflector that includes alternating layers of different insulating materials.

14. The device as defined by claim 12, wherein said insulating distributed Bragg reflector over at least a portion of said emitter region comprises an insulating Bragg reflector comprising alternating layers of SiO₂. and TiO₂.

15. The device as defined by claim 13, wherein a first reflector is disposed over said at least a portion of said emitter region, said first reflector comprising a DBR of alternating semiconductor materials of different composition, and whereby said insulating upper reflector is deposited over at least said first reflector.

16. The device as defined by claim 15, wherein said insulating upper reflector is disposed over at least said first reflector, and over said, base and emitter electrodes.

17. A method for making a light-emitting semiconductor structure, comprising the steps of:
providing a layered semiconductor structure that includes a substrate, a lower reflector and a semiconductor collector region disposed over said substrate, a semiconductor base region disposed over said collector region, and a semiconductor emitter region disposed over said base region;
providing, in said base region, at least one region exhibiting quantum size effects;
depositing collector, base, and emitter electrodes respectively coupled with said collector, base, and emitter regions;
disposing an insulating upper reflector over at least a portion of said emitter region, said disposing of an insulating upper reflector comprising disposing an insulating distributed Bragg reflector over at least a portion of said emitter region.

18. The method as defined by claim 17, wherein said step of disposing an insulating distributed Bragg reflector over at least a portion of said emitter region comprises providing an insulating Bragg reflector having alternating layers of different insulating materials.

19. The method as defined by claim 17, wherein said step of disposing an insulating distributed Bragg reflector over at least a portion of said emitter region comprises providing an insulating Bragg reflector having alternating layers of SiO₂ and TiO₂.

20. The method as defined by claim 17, further comprising disposing, over said at least a portion of said emitter region, a first reflector comprising a DBR of alternating semiconductor materials of different composition, and disposing said insulating upper reflector over at least said first reflector, after depositing of said collector, base, and emitter electrodes.

21. The method as defined by claim 20, wherein, as part of the formation of said layered semiconductor structure, depositing an oxidizable semiconductor layer adjacent said base region, forming a trench in said semiconductor structure, and oxidizing a central portion of said oxidizable layer to form an aperture.
